(19) United States
(12) Patent Application Publication
(10) Pub. No.: US 2024/0428851 A1
(43) Pub. Date: Dec. 26, 2024

(54) MEMORY WITH CHARGE SHARING BITLINES

(71) Applicant: Intel Corporation, Santa Clara, CA (US)

(72) Inventors: Amlan GHOSH, Mebane, NC (US); Saroj SATAPATHY, Austin, TX (US); Anandraj DEVARAJAN, Austin, TX (US); Jaydeep KULKARNI, Austin, TX (US); Feroze MERCHANT, Austin, TX (US)

(21) Appl. No.: 18/212,922

(22) Filed: Jun. 22, 2023

(51) Int. Cl. G11C 11/419; G06F 12/084; G11C 11/412

(52) U.S. Cl. CPC G11C 11/419; G06F 12/084; G11C 11/412

(57) ABSTRACT

Some embodiments relate generally to memory arrays having complementary bitlines. With some implementations, charge sharing to facilitate midrail read operations may be incorporated therein.

### TECHNICAL FIELD

Embodiments relate to the field of random access memory; and more specifically, to memory circuits for on-chip memory arrays.

### BACKGROUND

With the increased use of memory devices, further performance improvements in processing efficiency and implementation footprint are desired. Memory array innovations are needed, not only with existing but also for future, more advanced semiconductor processes.

### BRIEF DESCRIPTION OF THE DRAWINGS

The invention may best be understood by referring to the following description and accompanying drawings that are used to illustrate embodiments of the invention. In the drawings:

FIG. 1 shows a conventional bitcell circuit.

FIG. 2 shows another conventional bitcell circuit.

FIG. 3 shows a bitcell with a charge sharing circuit in accordance with some embodiments.

FIG. 4 shows a memory slice in accordance with some embodiments.

FIG. 5A shows a memory slice with a broken out bitcell section portion in accordance with some embodiments.

FIG. 5B shows the bitcell slice of FIG. 5A with a breakout of a portion of read circuitry in accordance with some embodiments.

FIG. 6 is a signal diagram illustrating read operation signals for the slice of FIGS. 5A and 5B in accordance with some embodiments.

FIG. 7 shows a memory array of bit memory slices in accordance with some embodiments.

FIG. 8 shows an alternative memory slice in accordance with some embodiments.

FIG. 9 is a computing system having memory bitcells in accordance with some embodiments.

FIG. 10 shows a processor of the system of FIG. 9 in accordance with some embodiments.

### DETAILED DESCRIPTION

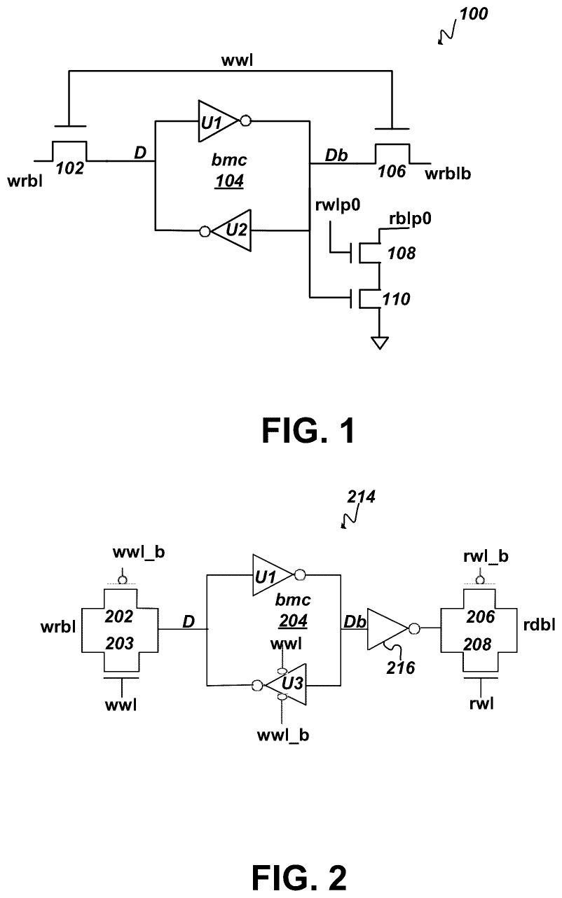

Contemporary integrated circuit designs implement numerous 1R1W (1 read port, one write port) and 2R1W (2 read ports, 1 write port) memory arrays, which can commonly constitute up to 25% or more of the total die area. These arrays often utilize 8 T (for 1R1W) or 10 T (for 2R1W) domino-read bitcells having dedicated read ports for improved performance and bitcell read-stability. FIG. 1 is an example of such a bitcell, an 8 T 1R1W bitcell in this case.

FIG. 1 illustrates a conventional 8 T domino r/w (read/write) bitcell 100 configured as a one-read-port-one-write-port (1R1W) bitcell. Bitcell 100 includes NMOS transistors 102, 106, 108, and 110, and a bit memory cell (bmc) 104, formed from a cross-coupled inverter pair, all coupled together as shown. It has a dedicated differential write bit line (wrbl/wrblb) for writing a bit data (D/Db) into the bmc and a separate dedicated single-ended read port (rblp0) for reading the data out of the cell. Such a bitcell is commonly used in integrated circuit cache memory arrays. Unfortunately, its layout height typically will not align with the standard logic cell height surrounding it and thus may require dedicated transition regions between bitcell segments and their peripheral read/write circuitry. Such frequently placed transition regions lead to inefficient layouts in processor technologies, which degrades the array area efficiency. Furthermore, these 8 T bitcells predominantly use NMOS transistors which results in diffusion under-utilization in some current, as well as anticipated, diffusion-gridded process technologies. The diffusion under-utilization will be even further exacerbated in upcoming complementary FET (CFET) technology implementations where balance between P and N type transistors will be at a premium.

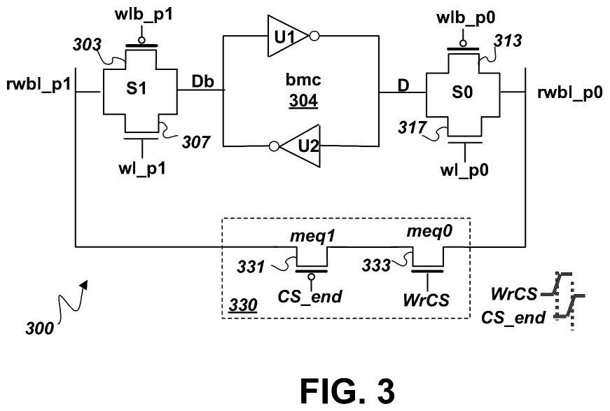

FIG. 2 shows a conventional 12 T static bitcell 214. Bitcell 214 includes a dedicated write-side passgate formed from P-type transistor 202 and N-type transistor 203, a dedicated read-side passgate formed from P-type transistor 206 and N-type transistor 208, an interruptible memory bit cell 204 formed from cross-coupled inverter U1 and tri-stateable inverter U3, and isolation inverter 216, all coupled together as shown. With a dedicated write bitline (wrbl) and an interruptible memory bitcell 204, this design allows for good writability. Likewise, the isolation inverter provides good read performance via the dedicated read bitline (rdbl). Moreover, with its use of 6 N-type devices and 6 P-type devices, this circuit has fully balanced diffusion usage.

However, when considering the higher number of required transistors, leakage power and area impact make this bitcell configuration less attractive than a domino bitcell with a smaller number of devices per bitcell, even when considering a possible transition cell penalty.

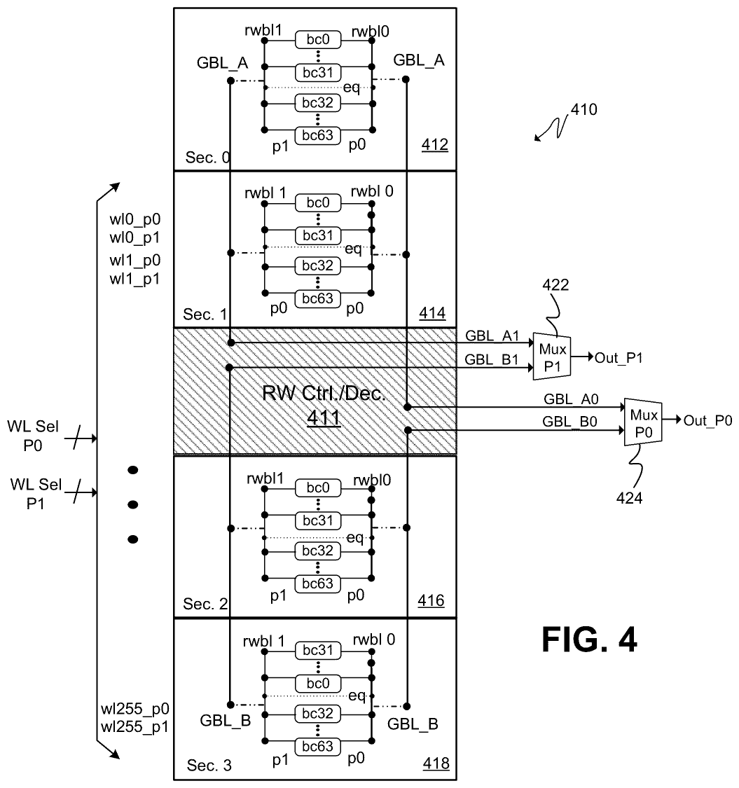

Accordingly, some disclosed approaches may use a balanced P/N bitcell (e.g., as illustrated in FIG. 3), which aims at improving layout area efficiency while facilitating reliable read/write performance for 1R1W and/or 2R1W implementations.

FIG. 3 shows a balanced P/N 8 T bitcell 300 that may be used for both 1R1W and/or 2R1W operations. Bitcell 300 generally includes bitline switch S1 (307), bitline switch S0 (313) and memory bitcell 304 (bmc), coupled together as shown to store complementary bit data D, Db.

Bitcell 300 uses a complementary bitline pair (rwbl_p1/rwbl_p0) that is used for both read and write operations. It also utilizes bitline switches (S1, S0) that are individually selectable through word lines wl_p1 and wl_p0, which allows for separate 2-read (P1, P0) configuration, although in some embodiments, only one of the ports may be used for a single read implementation. With this configuration, both bitlines can be used together for a differential write operation, while they can be used individually for single-ended read operations. In the depicted embodiment, the bitline switches are formed from passgates (P-type transistor 303 and N-type transistor 307 for S1 and P-type transistor 313 and N-type transistor 317 for S0). Accordingly, the word line control signals (wl_p1, wl_p0) are actually differential signals with complementary counterparts (wlb_p0 and wlb_p1). However, for sake of convenience, differential signals in this disclosure may simply be referred to without specific reference to their complementary counterpart, which in the figures is connoted with a “b”.)

In the depicted embodiment, a bitline charge sharing circuit 330 is also shown with the bitcell 300. Charge sharing circuitry 330 includes transistors meq1 (331) and meq0 (333) coupled in series between the bitlines (rwbl_p0, rwbl_p1). (Note that since the charge sharing circuitry may be shared by a number of bitcells, it is not expressed as being part of the bitcell circuit itself, and thus, the bitcell diffusion may still be considered as balanced with its 4 P-type and 4 N-type transistors.) The charge sharing transistors (meq0, meq1) serve to share charge between the bitlines prior to a read operation so that the bit line at ‘0 goes up, approaching a mid-Vcc level, while the bitline at “1 goes down, also approaching a mid Vcc level, albeit from a different direction. As used herein, performing a read from such a mid-level charged bitline is referred to as mid-rail operation. It should be appreciated that the charge sharing circuit will not necessarily make perfectly “equal” the two bitlines at a midrail level. Rather, the circuit will couple together the bitlines for a brief amount of time after a write operation occurs, but as a result of various factors (PVT, timing limitations, etc.), the bitlines may not perfectly equalize to the mid rail level. It is only necessary that they sufficiently approach mid rail level to facilitate satisfactory read operations.

In operation, the charge sharing transistors are controlled, as shown in the miniature timing diagram next to the transistors, to be briefly closed together (couple bitlines together) when a write column select (wrcs) signal goes from low to high. The circuit then opens (decouple the bitlines) when a cs_end signal goes high, thereby causing meq1 to turn off. So, both charge sharing transistors are turned on for a brief interval of time from when wrcs goes high to when cs_end goes high. In some embodiments, the cs_end signal may be generated off of the wres signal so as to ensure suitable deterministic and consistent timing operation.

As discussed above, the bitcell 300 does have the benefit of reasonably balanced device diffusion, as well as a relatively small number of required devices, especially when considering it may be used for 2R1W operation. However, without any further controls, as disclosed herein, this bitcell would likely have read stability issues. Accordingly, in some embodiments, a read bitline solution that pre-conditions the shared r/w bitlines to a midrail level prior to a read operation is used. furthermore, in some embodiments, separate precharge circuitry is not required because the charge sharing circuitry uses the complimentary bitline state from the previous write operation to attain the midrail levels on the bitlines. This midrail precharge has at least two distinct benefits: (i) the read stability of the bitcell is improved, and (ii) the read performance of the cell is also improved as for either port, the bit line only need charge, or discharge, from the midrail level, either to low or to high. For example, with a bitline ranging from Vss to Vcc, a read needs merely to transition from ½ Vcc (or thereabouts) to either full Vcc (on Read “1”) or to Vss (on Read ‘0). In addition, since there is no need for a separate precharge operation, write operation can happen in the same clock cycle as the read operation. For example, a write can occur during a low clock phase, while the read occurs during the high phase. Moreover, with the bitcell configuration employing gdual-ended bitline switch (transmission, or pass, gate) based write operations, very fast write operations may be facilitated.

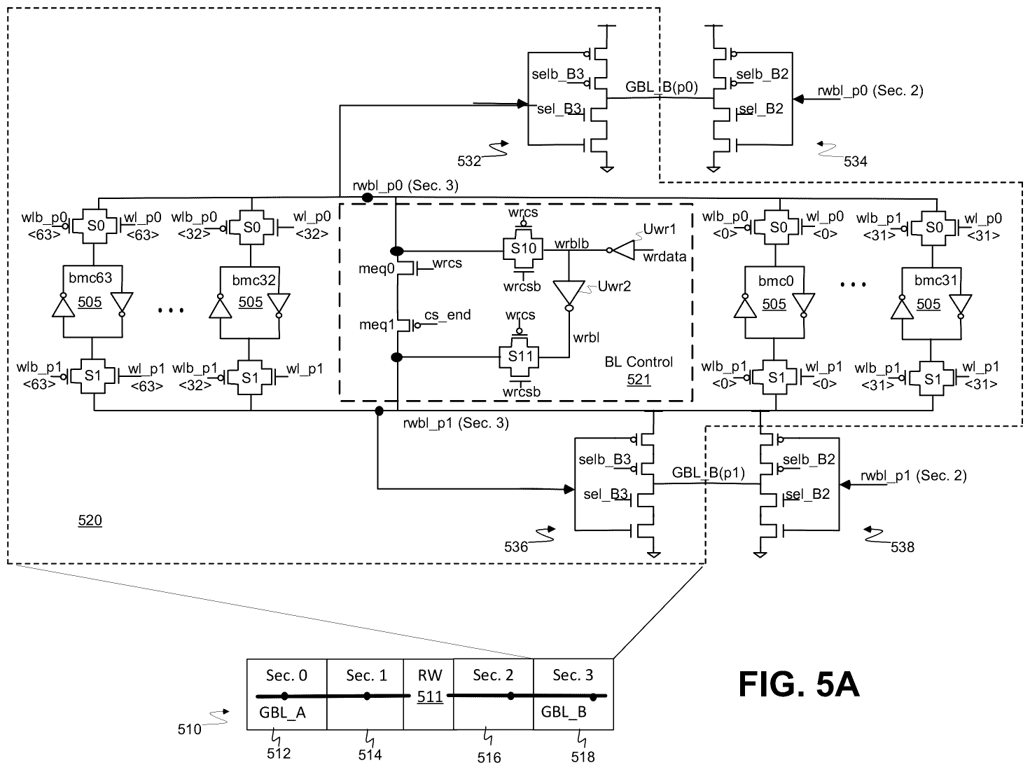

FIG. 4 is a block diagram showing a memory array slice 410 (column) of bitcells with charge sharing circuitry in accordance with some embodiments. In this implementation, slice 410 has 256 bitcells divided into four sections, Sec. 0 (412), Sec. 1 (414), Sec. 2 (416), and Sec. 3 (418). Each section has 64 bitcells (bc0 through bc63) coupled to a complementary local bitline pair (rwb10/rwbl1). As indicated, each section also includes charge sharing circuitry “eq” controllably coupled between a corresponding local bitline pair. In some embodiments, the charge sharing circuitry may be physically positioned in the middle of the 64 bitcells to reduce maximum distance from any one bitcell.

The rwb10 local bitlines facilitate port 0 reads, while the rwbl1 local bitlines facilitate port 1 reads. The local bitlines are coupled, on each side (po, p1) to associated global bit line segments GBL_A and GBL_B. For example, they may be coupled through selectable tri-gate switches such as tri-gateable pass gates. With this embodiment, each local bitline serves 64 bitcells, and each global bitline segment controllably couples together two local bitlines and thus serves 128 bitcells. (Note that the segments are labeled “A” and “B” in this disclosure but could have any other arbitrary designation. For example, in some disclosures, they may be referred to as “L” and “R” segments. Likewise, in this embodiment, the global bitlines are divided into two segments, but any other suitable configuration could be employed. For example, only 1, or multiple (more than two) separate, global bitline(s) could be used. For that matter, global bitlines may not even be employed, depending on design objectives and physical implementation parameters, although as slices and slice sections get larger, it may be helpful to use global/local bitline couplings to thwart limitations such as increased bitline capacitances.)

In the depicted embodiment, the slice includes wr/rd control circuitry 411, which may include write circuitry, read sense/latch circuitry, decode circuitry, and/or other timing and selection circuitry for writing and/or reading data from a selected one or two bitcells from the 256 bitcell slice. The wr/rd circuitry 411 includes port 1 read multiplexer/latch circuitry 422 and port 0 read multiplexer/latch circuitry 424, coupled as shown to the global bitline segments. (For convenience, clock and control signals and circuit components are not shown.) For a read operation, a wordline from a particular bitcell and particular port is asserted. The associated global bitline is activated, whereupon it “evaluates” the bit value from the selected bitcell/local bitline port, providing it to its associated read multiplexer, which latches it to its output. This can occur for a single read (one of the ports) or for two reads (both ports). However, if both ports are read, they should be from different bitcells.

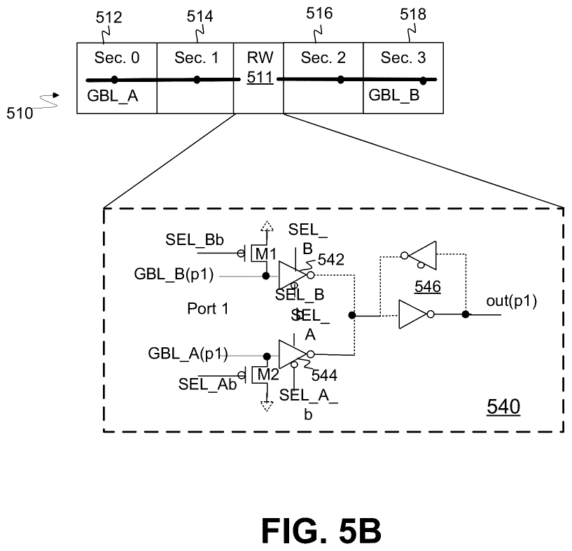

FIG. 5A schematically shows a portion 520 of a section 518 from a slice 510, which may implement some or all of the features of slice 410. Slice 510 has sections 512 through 518, along with a bitline control portion 521. Portion 520 illustrates a more detailed example for implementing a bitcell section (Sec. 3 in this case).

Slice section portion 520 generally includes 64-bit memory cells 505 (bmc 0 through bmc 63) coupled as shown to complementary rw bitlines (rwbl_p0, rwbl_p1) through associated bitline switches S0, S1. Also included is bitline control circuitry 521 and local bitline coupling switches 532 through 538. Switch 532 controllably couple the port 0 local bitline (rwbl_p0) to its associated global bitline, global bitline B for port 0 in this case. Also shown is another local bitline switch 534 for coupling the section 2 (516) port 0 local bitline to the global B bitline as well. (There would likely be similar circuitry, not shown, for sections 0 and 1, which would couple to the GBL_A global bitline segment.) Likewise, local bitline switch 536 controllably couples the port 1 local bitline (rwbl_p1) from section 3 to its associated global bitline (GBL_B). Also shown, as well, is a local bitline switch 538 for coupling the port 1 local bitline from section 2 to the GBL_B global bitline segment. (Note that for 2r1w capability, there may be separate control lines for switches 532 and 536, as well as for 534 and 538.)

Bitline control circuitry 521 includes write inverters (Uwr1, Uwr2), write select switches (S10, S11) and charge sharing circuitry switches (meq0, meq1) coupled as shown. (It should be appreciated that this exemplary circuit portion is not exhaustive with regard to all aspects of bitline control. Rather, elements pertinent for controlling the bitline (midrail) charge sharing features are shown for describing how bitline charge sharing could occur in cooperation with write operations in some embodiments.) The write select switches (S10, S11) are controlled by differential write select signals (wrcs/wrcsb), referred, for convenience, as simply as write select (wrcs). When the wrcs signal is asserted (low in this depiction), switches S10 and S11 turn on, thereby writing write data (wrdata) from inverter Uwr1 onto the rw bitlines (rwbl_p0, rwbl_p1). This also turns off meq0, allowing the bitlines to be written to without detraction from the charge sharing circuit. When wrcs de-asserts (high), the charge sharing circuit turns on, for a brief amount of time as defined by the cs_end signal (discussed with reference to FIG. 3) and effectuates the midrail bitline charge sharing as discussed previously. From here, while wrcs is de-asserted (high), a read operation occurs, either for one or for both of the ports.

FIG. 5B shows memory slice 510 but this time, illustrating a more detailed circuit portion 540 from the r/w section 511. Circuit portion 540 includes a multiplexer formed from selectable switches (inverting switches in this example) 542, 544 coupled to an output read port (port 1 in this example) memory cell driver 546. The multiplexer receives the port 1 global bitline segment signals (GBL_A(p1, GBL_B(p1)) from global bitline segments A, B, respectively. For example, global bitline segment signals for segment B are indicated in FIG. 5A. (For convenience, similar multiplexer circuitry for port 0 is not when but could also be included in r/w section 511.)

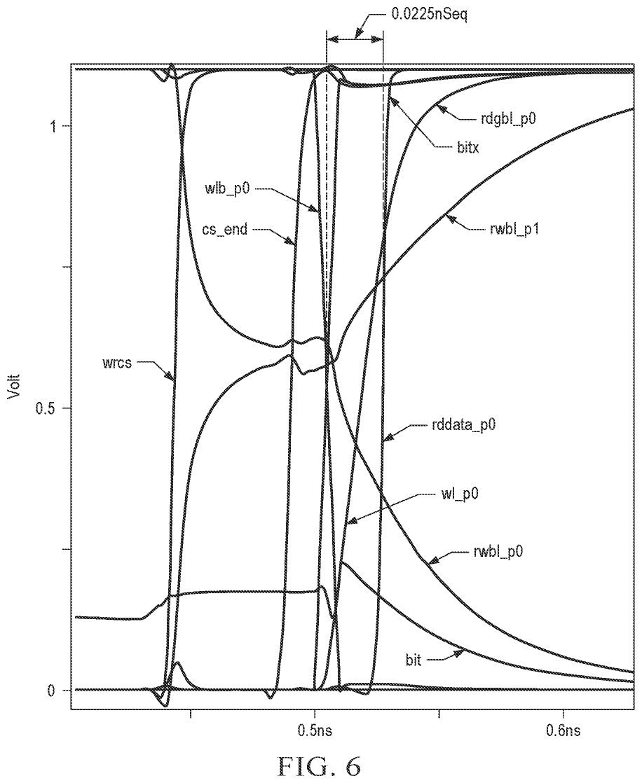

With reference to FIGS. 5A and 5B and additional reference to FIG. 6, read and write operations will be discussed in further detail. Note that the signal labels “bit” and “bitx” correspond to “D” and “Db” in FIG. 3, respectively. In addition, for ease of explanation and so as not to make the schematics and signal representations unnecessarily busy, not all signals are shown. For example, it is assumed that a common clock signal is used to generate the various read and write selection and control signals with desired phase and delay relationships. For purposes of the following read and write descriptions, reference is made to the “clock”. It should be assumed that the clock generally corresponds to the write select signal (wrcs). That is, when clock is low, it may be assumed that wrcs is low.

During a low clock cycle phase, rwbl_p0 and rwbl_p1 are driven to complimentary write data values. At the beginning of evaluate (high clock) phase, the write select switches S10, S11 are turned off by the rise of wrcs and fall of wrcsb so that rwbl_p0 and rwbl_p1 are floated, having already been initialized with the complementary write-data values. While rwbl_p0 and rwbl_p1 are floating, meq0 and meq1 are briefly turned on causing the bitlines to charge share thus driving them both to approach ˜Vcc/2. This is achieved by wres rising (meq0 turns on) and ensuring that the starting state of cs_end is ‘0 (meq1 stays on). A few inverter delay states later, for example, cs_end turns off meq1 and cuts off the charge sharing path between the two local bitlines, just before the wordline (w1) for a selected bit memory cell read port is triggered. Since stability of the bit memory cell is vulnerable during read operations, providing a midrail voltage at the local bitlines prior to the read operation improves bitcell stability.

FIG. 6 shows representative simulation waveforms during a read “0” operation. During a low clock (wrcs) phase, rwbl_p0 and rwbl_p1 are parked at “1” and “0” based on the applied write state. At the beginning of the read operation, wrcs rises (wrcsb falls), switches S10, S11 turn off and meq0 turns on. During this period, both meq0 and meq1 are fully turned on, rwbl_p0 starts to discharge towards midrail voltage whereas rwbl_p1 goes up towards midrail. Rising of cs_end (delayed inverted version of wrcs) cuts off the charge sharing process by turning off meq1. At this point, Read wordline rwl_p0 for a selected entry fires and allows the selected bitline rwbl_p0 to be evaluated based on the content of the bitcell. In this example, rwbl_p0 is going down since the selected bitcell is storing “0” at the bit (D) node. Assuming one of the “B” section entries has been selected, Selb_B0 and Sel_B0 allow the evaluated rwbl_p0 value to be propagated to the global bitline (GBL_p0) and store the output at the read data latch 546. The section output select signals (Selb_B0 and Sel_B0) are clocked, returning the feed forward tristate inverter 532 to a tristate condition for a next read operation.

With some integrated read-write embodiments discussed herein, write operations happen during low phases of the clock cycle. The local bitlines (rwbl_p0, rwbl_p1) are driven by write bitline drivers (switches S10, S11) with these paths turned off during read operations with the rising of wrcs and falling of wrcsb. The two local bitlines are set to the correct value based on the write data input. Both port side wordlines (wl_p0, wl_p1, along with their respective complimentary counterparts (wlb_p0, wlb_p1) for a selected bitcell are turned on to start a successful write. Since write happens through the bitcell switches (transmission gates S0, S1) in a differential manner, write contention is overcome from both sides, resulting in a very fast and efficient write operation without requiring a dedicated write-assist circuit technique.

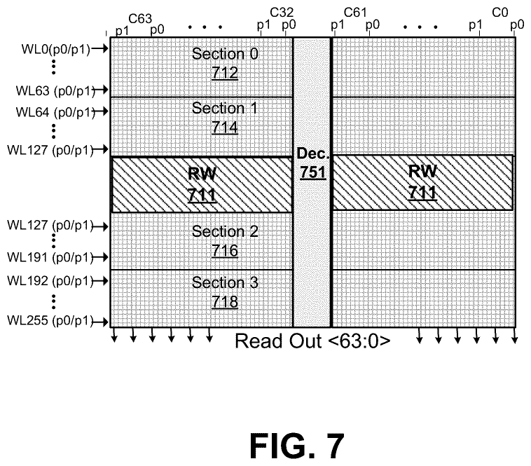

FIG. 7 shows an exemplary memory array in accordance with some embodiments. The array includes 64 slices (or columns) each having of 256 bitcells. These slices may be configured as previously discussed. The array has a rw circuit block 711 substantially disposed in the middle of the it cell slices such that it is not excessively distant from any on one bitcell in a slice. (In this embodiment, it would not be more than 64 bitcells away from any one bitcell.) Similarly, the array also has a decode circuit block 751, which is disposed centrally between the 64 columns (or slices). It should be appreciated that control circuitry for controlling read and/or write operations may be located, wholly and/or partially, in r/w circuit 711, decode circuit 751, or in both r/w and decode blocks, as deemed appropriate for a particular design. In some embodiments, this array may be used to implement on-chip cache memory such as L1, L2 and/or L3 cache memory.

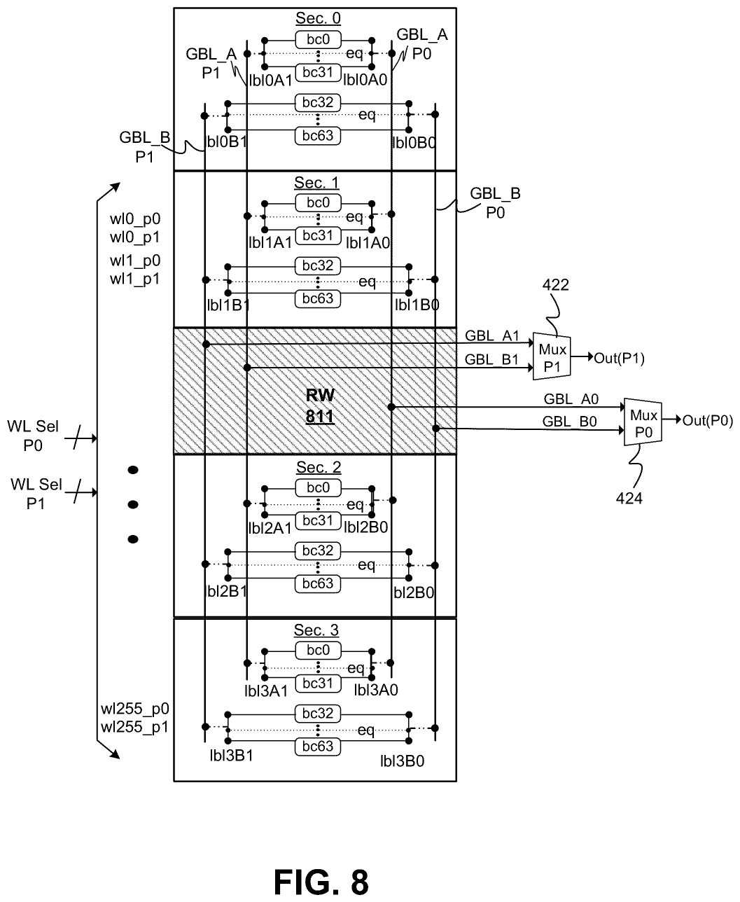

FIG. 8 shows another embodiment of a bitcell slice in accordance with some embodiments. This slice is similar with that of FIG. 4 except that its local and global bitlines may be implemented differently. In this embodiment, the local bit lines in each section are divided into two sub-segments, each one being controllably coupled to one of the global segments, A or B. In this way, the bitcells for each segment (A, B) are distributed more evenly throughout the slice, which may reduce segment constituent inconsistencies, e.g., in timing, PVT, defect occurrence, etc.

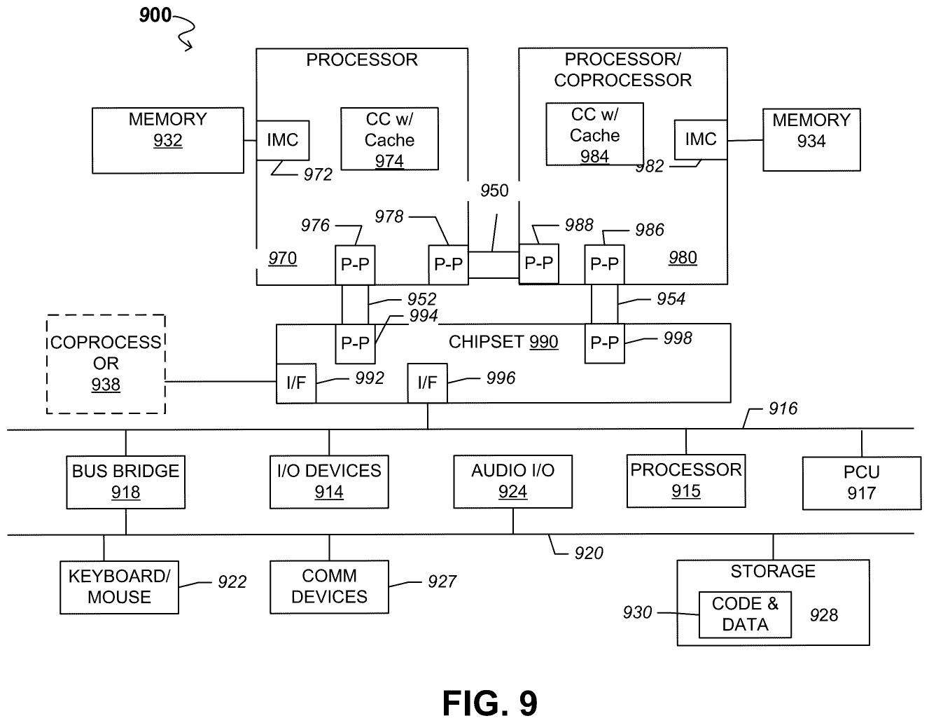

FIG. 9 illustrates an example computing system. Multiprocessor system 900 is an interfaced system and includes a plurality of processors including a first processor 970 and a second processor 980 coupled via an interface 950 such as a point-to-point (P-P) interconnect, a fabric, and/or bus. In some examples, the first processor 970 and the second processor 980 are homogeneous. In some examples, first processor 970 and the second processor 980 are heterogenous. Though the example system 900 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 970 and 980 are shown including integrated memory controller (IMC) circuitry 972 and 982, respectively. Processor 970 also includes interface circuits 976 and 978, along with core complex with cache sets 974. Cache and/or register files, for example, in a core complex may be implemented with memory as disclosed herein. Similarly, second processor 980 includes interface circuits 986 and 988, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 970, 980 may exchange information via the interface 950 using interface circuits 978, 988. IMCs 972 and 982 couple the processors 970, 980 to respective memories, namely a memory 932 and a memory 934, which may be portions of main memory locally attached to the respective processors.

Processors 970, 980 may each exchange information with a network interface (NW I/F) 990 via individual interfaces 952, 954 using interface circuits 976, 994, 986, 998. The network interface 990 (e.g., one or more of an interconnect, bus, and/or fabric, and in some examples is a chipset) may optionally exchange information with a coprocessor 938 via an interface circuit 992. In some examples, the coprocessor 938 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache may be included in either processor 970, 980 or outside of both processors, yet connected with the processors via an interface such as P-P interconnect, such that either or both processors' local cache information may be stored in the shared cache if a processor is placed into a low power mode. Some of these cache structures may be implemented with charge sharing bitline memory arrays as discussed herein.

Network interface 990 may be coupled to a first interface 916 via interface circuit 996. In some examples, first interface 916 may be an interface such as a Peripheral Component Interconnect (PCI) interconnect, a PCI Express interconnect, or another I/O interconnect. In some examples, first interface 916 is coupled to a power control unit (PCU) 917, which may include circuitry, software, and/or firmware to perform power management operations with regard to the processors 970, 980 and/or co-processor 938. PCU 917 provides control information to one or more voltage regulators (not shown) to cause the voltage regulator(s) to generate the appropriate regulated voltage(s). PCU 917 also provides control information to control the operating voltage generated. In various examples, PCU 917 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 917 is illustrated as being present as logic separate from the processor 970 and/or processor 980. In other cases, PCU 917 may execute on a given one or more of cores (not shown) of processor 970 or 980. In some cases, PCU 917 may be implemented as a microcontroller (dedicated or general-purpose) or other control logic configured to execute its own dedicated power management code, sometimes referred to as P-code. In yet other examples, power management operations to be performed by PCU 917 may be implemented externally to a processor, such as by way of a separate power management integrated circuit (PMIC) or another component external to the processor. In yet other examples, power management operations to be performed by PCU 917 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 914 may be coupled to first interface 916, along with a bus bridge 918 which couples first interface 916 to a second interface 920. In some examples, one or more additional processor(s) 915, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 916. In some examples, second interface 920 may be a low pin count (LPC) interface. Various devices may be coupled to second interface 920 including, for example, a keyboard and/or mouse 922, communication devices 927 and storage circuitry 928. Storage circuitry 928 may be one or more non-transitory machine-readable storage media as described below, such as a disk drive or other mass storage device which may include instructions/code and data 930 and may implement the storage in some examples. Further, an audio I/O 924 may be coupled to second interface 920. Note that other architectures than the point-to-point architecture described above are possible. For example, instead of the point-to-point architecture, a system such as multiprocessor system 900 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality.

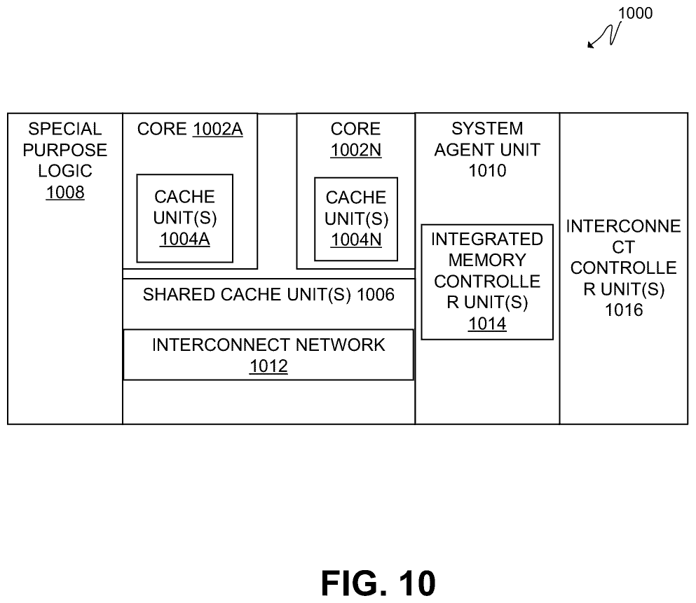

FIG. 10 illustrates a block diagram of an example processor and/or SoC 1000 that may have one or more cores and an integrated memory controller. The solid lined boxes illustrate a processor 1000 with cores 1002(A-N), system agent unit circuitry 1010, and a set of one or more interface controller unit(s) circuitry 1016. Also included are a set of one or more integrated memory controller unit(s) circuitry 1014 in the system agent unit circuitry 1010, and special purpose logic 1008, as well as a set of one or more interface controller units circuitry 1016. Note that the processor 1000 may be one of the processors 970 or 980, or co-processor 938 or 915 of FIG. 9.

Thus, different implementations of the processor 1000 may include: 1) a CPU with the special purpose logic 1008 being integrated graphics and/or scientific (throughput) logic (which may include one or more cores, not shown), and the cores 1002(A)-(N) being one or more general purpose cores (e.g., general purpose in-order cores, general purpose out-of-order cores, or a combination of the two); 2) a coprocessor with the cores 1002(A)-(N) being a large number of special purpose cores intended primarily for graphics and/or scientific (throughput); and 3) a coprocessor with the cores 1002(A)-(N) being a large number of general purpose in-order cores. Thus, the processor 1000 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 1000 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), N-type metal oxide semiconductor (NMOS), gate all around (GAA) such as CFET processes, and the like.

A memory hierarchy includes one or more levels of cache unit(s) circuitry 1004(A)-(N) within the cores 1002(A)-(N), a set of one or more shared cache unit(s) circuitry 1006, and external memory (not shown) coupled to the set of integrated memory controller unit(s) circuitry 1014. The set of one or more shared cache unit(s) circuitry 1006 may include one or more mid-level caches, such as level 2 (L2), level 3 (L3), level 4 (L4), or other levels of cache, such as a last level cache (LLC), and/or combinations thereof. Any such cache units may incorporate memory with bitcells as discussed herein. While in some examples interface network circuitry 1012 (e.g., a ring interconnect) interfaces the special purpose logic 1008 (e.g., integrated graphics logic), the set of shared cache unit(s) circuitry 1006, and the system agent unit circuitry 1010, alternative examples use any number of well-known techniques for interfacing such units. In some examples, coherency is maintained between one or more of the shared cache unit(s) circuitry 1006 and cores 1002(A)-(N). In some examples, interface controller units circuitry 1016 couple the cores 1002 to one or more other devices 1018 such as one or more I/O devices, storage, one or more communication devices (e.g., wireless networking, wired networking, etc.), etc.

In some examples, one or more of the cores 1002(A)-(N) are capable of multi-threading. The system agent unit circuitry 1010 includes those components coordinating and operating cores 1002(A)-(N). The system agent unit circuitry 1010 may include, for example, power control unit (PCU) circuitry and/or display unit circuitry (not shown). The PCU may be or may include logic and components needed for regulating the power state of the cores 1002(A)-(N) and/or the special purpose logic 1008 (e.g., integrated graphics logic). The display unit circuitry is for driving one or more externally connected displays.

The cores 1002(A)-(N) may be homogenous in terms of instruction set architecture (ISA). Alternatively, the cores 1002(A)-(N) may be heterogeneous in terms of ISA; that is, a subset of the cores 1002(A)-(N) may be capable of executing an ISA, while other cores may be capable of executing only a subset of that ISA or another ISA.

### EXAMPLES

Illustrative examples of the technologies disclosed herein are provided below. An embodiment of the technologies may include any one or more, and any compatible combination of, the examples described below.

Example 1 is an apparatus that comprises a plurality of bitcells and charge sharing circuitry. The bitcells each have a bit memory cell (bmc) including first and second complementary bit nodes, a first bitline switch to couple the first bit node to a first bitline, and a second bitline switch to couple the second bit node to a second bitline. The charge sharing circuitry is coupled between the first and second bitlines to share charge between the bitlines after a write operation and prior to a next read operation.

Example 2 includes the subject matter of Example 1, and wherein the memory bit cells each consist of an equal number of P and N type transistors.

Example 3 includes the subject matter of any of examples 1 or 2, and wherein the bitline switches are pass gates formed from a pair of N and P type transistors.

Example 4 includes the subject matter of any of examples 1-3, and wherein the write operation includes a differential write to the first and second bitlines.

Example 5 includes the subject matter of any of examples 1-4, and wherein the read operation is a single-ended read from one of the bitlines.

Example 6 includes the subject matter of any of examples 1-5, and wherein the read operation is a single-ended read from the first bitline from a selected one of the bitcells and a single-ended read from the second bitline from a selected different one of the bitcells.

Example 7 is a memory array having a plurality of memory slices each having bitcells and charge sharing circuitry in accordance with any of the examples of examples 1-6.

Example 8 is an integrated circuit having a block of cache memory in accordance with any of the examples of examples 1-7.

Example 9 includes the subject matter of any of examples 1-8, and wherein the slices comprise multiple sections of bitcells and charge sharing circuits coupled to the bitlines, which are local bitlines, the local bitlines being coupled to global bitlines to provide output data from the read operation.

Example 10 is an integrated circuit having a memory array that includes a plurality of memory slices. The plurality of memory slices each include complementary bitlines and charge sharing circuitry. The charge sharing circuitry is controllably coupled between the bitlines to turn on and share charge between the bitlines for a period of time after a write operation has sufficiently completed and then to turn off and decouple them from each other prior to a read operation.

Example 11 includes the subject matter of example 10, and wherein the charge sharing circuitry comprises a first switch that is controlled off of a write select signal to turn on when the write is completing.

Example 12 includes the subject matter of any of examples 10-11, and wherein the charge sharing circuitry comprises a second switch in series with the first switch to turn off upon the end of the period of time after the first switch has turned on.

Example 13 includes the subject matter of any of examples 10-12, and wherein the second switch is controlled by a signal that is a delay of the write select signal.

Example 14 includes the subject matter of any of examples 10-13, and wherein each slice includes a plurality of 8 T bitcells coupled to the bitlines.

Example 15 includes the subject matter of any of examples 10-14, and wherein the 8T bitcells each comprise four N-type devices and four P-type devices.

Example 16 includes the subject matter of any of examples 10-15, and wherein the P and N type devices are formed from a GAA CFET process.

Example 17 is a system that includes a processor and a power supply. The processor has cache memory formed from an array with a plurality of memory slices each including complementary bitlines and charge sharing circuitry controllably coupled between the bitlines to turn on and share charge between the bitlines for a period of time after a write operation has sufficiently completed and then to turn off and decouple them from each other prior to a read operation. The power supply is coupled to the processor to provide it with one or more power supply rails.

Example 18 includes the subject matter of example 17, and wherein the charge sharing circuitry comprises a first switch that is controlled off of a write select signal to turn on when the write is completing.

Example 19 includes the subject matter of any of examples 17-18, and wherein the charge sharing circuitry comprises a second switch in series with the first switch to turn off upon the end of the period of time after the first switch has turned on.

Example 20 includes the subject matter of any of examples 17-19, and wherein the second switch is controlled by a signal that is a delay of the write select signal.

Example 21 includes the subject matter of any of examples 17-20, and wherein each slice includes a plurality of 8 T bitcells coupled to the bitlines.

Example 22 includes the subject matter of any of examples 17-21, and wherein the 8T bitcells each comprise four N-type devices and four P-type devices.

Example 23 includes the subject matter of any of examples 17-22, and wherein the P and N type devices are formed from a GAA CFET process.

Example 24 includes the subject matter of any of examples 17-23, and wherein the proc processor is formed on multiple chiplets within a system on package having chiplets formed from different semiconductor processes.

Example 25 includes the subject matter of any of examples 17-24, and wherein the processor has a graphics processing unit comprising at least some of the memory slices.

Example 26 is a chip that comprises a memory array. The memory array has first and second sets of bitcell slices and a decode section that is disposed between the first and second bit slice sets. Each bitcell slice includes a plurality of bitcells coupled to complementary bitlines and at least one charge sharing circuit is coupled to the bitlines to facilitate midrail read operations, and the complementary bitlines provide dual read ports.

Example 27 includes the subject matter of example 26, and wherein each slice has multiple bitcell sections coupled together through global bitlines.

Example 28 includes the subject matter of any of examples 26-27, and wherein each bitcell section has two or more separate sets of local bitlines coupled to the global bitlines.

Example 29 includes the subject matter of any of examples 26-28, and wherein the complementary bitlines are coupled to the global bitlines through trigateable switches.

Example 30 is an apparatus that includes a plurality of bitcell means and charge sharing means. The plurality of bitcell means is coupled to a bitline. The charge sharing means is coupled to the bitline to facilitate midrail reads.

Example 31 includes the subject matter of example 30, and wherein the bitcell means includes a plurality of bitcells each having equal numbers of P and N type transistors.

Example 32 includes the subject matter of any of examples 30-31, and wherein the bitcells have bitline switches comprising passgates formed from a pair of N and P type transistors.

Example 33 includes the subject matter of any of examples 30-32, and wherein each bit cell has separately controllable bitline switches.

Example 34 includes the subject matter of any of examples 30-333, and wherein the bitline switches facilitate dual port read operations.

Example 35 includes the subject matter of any of examples 30-34, and wherein the bitline switches facilitate a differential write operation.

Example 36 includes the subject matter of any of examples 30-35, and wherein the bitcell means are part of a cache memory array means.

Example 37 is a method for reading data from a dual read single write memory slice. The method includes applying a first clock phase in a clock cycle to write data onto complementary bitlines in the slice. It also includes sharing charge between the bitlines after the first phase transitions to a second phase and reading data from one or both of the bitlines within the second phase.

Example 38 includes the subject matter of claim 37, and wherein sharing charge between the bitlines after the first phase transitions to a second phase includes turning on a charge sharing circuit and then turning it off for a period of time after the first phase transitions to the second phase.

Example 39 includes the subject matter of example 38, and further including selecting a local bitline to read the data onto a global bit line.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. Different circuits or modules may share ore even consist of common components. for example, A controller circuit may be a circuit to perform a first function and at the same time, the same controller circuit may also be a circuit to perform another function, related or not related to the first function.

The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around transistors including so-called CFET transistors, Tunneling FET (TFET), Square Wire, or Rectangular Ribbon Transistors, ferroelectric FET (FeFETs), or other devices implementing transistor functionality like carbon nanotubes or spintronic devices. Those skilled in the art will appreciate that other transistors, for example, Bi-polar junction transistors (BJT PNP/NPN), BICMOS, CMOS, GaN, etc., may be used without departing from the scope of the disclosure.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

While embodiments have primarily been described in relation to an 8 T bitcells with balanced P-type/N-type transistor distribution, it should be appreciated that the invention is not so limited. Other configurations, with more or less transistors and with unbalanced diffusion distribution could be used with some or many of the innovative features described herein. Likewise, the described memory slices may be implemented in any desired configuration such as small arrays, large arrays, arrays with local/global bit line structures and those with only local bitline. Moreover, the described innovative features may be used with static, dynamic and combinations of static and dynamic memory circuit implementations.

What is claimed is:

1. An apparatus, comprising:
a plurality of bitcells each having a bit memory cell (bmc) including first and second complementary bit nodes, a first bitline switch to couple the first bit node to a first bitline, and a second bitline switch to couple the second bit node to a second bitline; and
charge sharing circuitry coupled between the first and second bitlines to share charge between the bitlines after a write operation and prior to a next read operation.

2. The apparatus of claim 1, wherein the memory bit cells each include an equal number of P and N type transistors.

3. The apparatus of claim 1, wherein the bitline switches are pass gates formed from a pair of N and P type transistors.

4. The apparatus of claim 1, wherein the write operation includes a differential write to the first and second bitlines.

5. The apparatus of claim 4, wherein the read operation is a single-ended read from one of the bitlines.

6. The apparatus of claim 5, wherein the read operation is a single-ended read from the first bitline from a selected one of the bitcells and a single-ended read from the second bitline from a selected different one of the bitcells.

7. The apparatus of claim 1, further comprising a memory array having a plurality of memory slices each having bitcells and charge sharing circuitry.

8. The apparatus of claim 7, wherein the memory array further comprises a block of cache memory.

9. The apparatus of claim 7, wherein the memory slices comprise multiple sections of bitcells and charge sharing circuits coupled to the bitlines, which are local bitlines, the local bitlines being coupled to global bitlines to provide output data from the read operation.

10. An integrated circuit having a memory array, comprising:
a plurality of memory slices each including:
complementary bitlines; and
charge sharing circuitry controllably coupled between the bitlines to turn on and share charge between the bitlines for a period of time after a write operation has sufficiently completed and then to turn off and decouple them from each other prior to a read operation.

11. The integrated circuit of claim 10, wherein the charge sharing circuitry comprises a first switch that is controlled off of a write select signal to turn on when the write is completing.

12. The integrated circuit of claim 11, wherein the charge sharing circuitry comprises a second switch in series with the first switch to turn off upon the end of the period of time after the first switch has turned on.

13. The integrated circuit of claim 12, wherein the second switch is controlled by a signal that is a delay of the write select signal.

14. The integrated circuit of claim 10, wherein each slice includes a plurality of 8 T bitcells coupled to the bitlines.

15. The integrated circuit of claim 14, wherein the 8 T bitcells each comprise four N-type devices and four P-type devices.

16. The integrated circuit of claim 15, wherein the P and N type devices are formed from a GAA CFET process.

17. A system, comprising:
a processor having cache memory formed from an array with a plurality of memory slices each including:
complementary bitlines;
charge sharing circuitry controllably coupled between the bitlines to turn on and share charge between the bitlines for a period of time after a write operation has sufficiently completed and then to turn off and decouple them from each other prior to a read operation; and
a power supply coupled to the processor to provide it with one or more power supply rails.

18. The system of claim 17, wherein the charge sharing circuitry comprises a first switch that is controlled off of a write select signal to turn on when the write is completing.

19. The system of claim 18, wherein the charge sharing circuitry comprises a second switch in series with the first switch to turn off upon the end of the period of time after the first switch has turned on.

20. The system of claim 19, wherein the second switch is controlled by a signal that is a delay of the write select signal.

21. The system of claim 17, wherein each slice includes a plurality of 8 T bitcells coupled to the bitlines.

22. The system of claim 21, wherein the 8 T bitcells each comprise four N-type devices and four P-type devices.

23. The system of claim 22, wherein the P and N type devices are formed from a GAA CFET process.

24. The system of claim 17, wherein the processor is formed on multiple chiplets within a system on package having chiplets formed from different semiconductor processes.

25. The system of claim 17, wherein the processor has a graphics processing unit comprising at least some of the memory slices.
